(19) United States
(12) Patent Application Publication
(10) Pub. No.: US 2025/0347733 A1
(43) Pub. Date: Nov. 13, 2025

(54) METAL DETECTION SENSOR BASED ON DUAL RESONANCE

(71) Applicant: Prince Sattam Bin Abdulaziz University (PSAU), Al Kharj (SA)

(72) Inventors: Mahmoud Eyad Mahmoud Abushab, Al Kharj (SA); Omar F. Siddiqui, Madinah (SA); Maged Abdullah Aldhaeebi, Al Kharj (SA); Thamer Almoneef, Al Kharj (SA)

(73) Assignee: Prince Sattam Bin Abdulaziz University (PSAU), Al Kharj (SA)

(21) Appl. No.: 18/661,606

(22) Filed: May 11, 2024

(51) Int. Cl. G01R 31/28; G01N 22/00

(52) U.S. Cl. CPC G01R 31/281; G01N 22/00

(57) ABSTRACT

An apparatus comprising of two microstrip resonators placed on two parallel surfaces of a planar dielectric substrate, electrically disconnected from each other. The apparatus further comprising a microstrip T-resonator comprising a transmission line and a stub, placed substantially in a middle of the transmission line, placed on the first surface of a planar dielectric substrate. The apparatus further comprises a split-ring resonator comprising two split rings, placed on the second surface of the substrate such that the adjacent edge of the split rings substantially aligns with the open-ended edge of the stub in the first surface. The apparatus further comprises two ground conductors, each placed on the opposite sides of the microstrip T-resonator and split-ring resonator. The apparatus further comprises a microstrip L-resonator, instead of the microstrip T-resonator, coupled to a rectifying circuit block to provide a DC voltage output signal.

### TECHNICAL FIELD

At least one example generally relates to sensors, and more particularly to metal detection sensors, employing a dual resonator structure for detecting metals.

### BACKGROUND

Quality check of the printed circuit boards (PCB) during production is a critical step, as faults in metal traces, such as shorts, breaks, or variations in thickness in manufactured PCBs can compromise the functionality of electronic devices, leading to significant costs and overheads for businesses. Even the presence of small amount of metal contaminants within the materials' streams used in PCBs can significantly impact their integrity, safety, and compliance. Existing metal detection methods typically suffer from limitations in terms of sensitivity, resolution, or adaptability, making it challenging to meet the stringent demands of electronic devices industry especially for products that need to qualify and comply with industry or military standards. Consequently, advanced metal detection sensors are needed that provide superior performance, precision, sensitivity, and reliability.

The background description provided here is for the purpose of generally presenting the context of the disclosure. Unless otherwise indicated here, the material described in this section is not prior art to the claims in this application and are not admitted to be prior art by inclusion in this section.

### BRIEF DESCRIPTION OF THE DRAWINGS

At least one embodiment may be understood more fully from detailed description given below and from accompanying drawings, which, however, should not be taken to be limiting, but are for explanation and understanding.

FIG. 1 is a schematic that illustrates a structure of a microstrip resonator placed on a first surface of a planar dielectric substrate with a ground conductor placed on a second surface of the planar dielectric substrate, in accordance with at least one example.

FIG. 2 is a plot that illustrates the frequency response of the structure of the microstrip T-resonator of FIG. 1, in accordance with at least one example.

FIG. 3 is a schematic that illustrates a structure of a split-ring resonator, placed on the second surface of the planar dielectric substrate with a ground conductor placed on the first surface of the planar dielectric substrate, in accordance with at least one example.

FIG. 4 is a plot that illustrates the frequency response of the structure of the split-ring resonator of FIG. 3, in accordance with at least one example.

FIG. 5 is a schematic that illustrates a dual resonator sensor based on dual resonance, wherein a microstrip T-resonator and a split-ring resonator (SRR) are placed on parallel surfaces of a planar dielectric substrate, in accordance with at least one example.

FIG. 6 is a plot that illustrates the frequency response of the dual resonator sensor illustrated in FIG. 5, in accordance with at least one example.

FIG. 7 is a plot that illustrates a change in the frequency response, when a material block is in the proximity of 1 mm to 5 mm of the dual resonator sensor, in accordance with at least one example.

FIG. 8 is a schematic that illustrates a dual resonator device, wherein a microstrip L-resonator and a split-ring resonator are placed on parallel surfaces of a planar dielectric substrate and a rectifying circuit block is utilized to obtain a DC voltage output signal, in accordance with at least one example.

FIG. 9 is a plot that illustrates the frequency response of the dual resonator device illustrated in FIG. 8 when a metal mass is placed in the proximity (varying the distance between 5 mm and 20 mm), in accordance with at least one example.

FIG. 10 is a plot that illustrates a change in the DC voltage output in the transmittance window of the frequency sweep of the structure of FIG. 8 when a metal is placed in the proximity of 1 mm to 5 mm, in accordance with at least one example.

FIG. 11A is a schematic that illustrates an electric field magnitude plot of the dual resonator sensor of FIG. 5, in accordance with at least one example.

FIG. 11B is a schematic that illustrates an electric field magnitude plot of the dual resonator device of FIG. 8, in accordance with at least one example.

FIG. 12 is a schematic that illustrates an example array structure for the dual resonator device, in accordance with at least one example.

FIG. 13 is a schematic that illustrates an example structure for the dual resonator sensor, wherein the end of the stub of the microstrip T-resonator is chamfered, in accordance with at least one example.

FIG. 14 is a plot that illustrates the frequency response of the dual resonator sensor of FIG. 13, in accordance with at least one example.

FIG. 15 is a schematic that illustrates an example structure for the dual resonator sensor, wherein the split-ring resonator comprises circular rings, in accordance with at least one example.

FIG. 16 is a schematic that illustrates an example structure for the dual resonator sensor, wherein the rings of the split-ring resonator include more than one split, in accordance with at least one example.

FIG. 17 is a schematic that illustrates an example structure for the dual resonator sensor, wherein the ground conductors of the resonators overlap, in accordance with at least one example.

FIG. 18 is a schematic that illustrates a system architecture diagram of a dual resonator scanner device used to scan a body for concealed metal objects, in accordance with at least one example.

FIG. 19 is a flowchart that illustrates the method of the dual resonator device metal detection, in accordance with at least one example.

### GLOSSARY OF SYMBOLS

| | |
|---|---|
| PCB | Printed circuit board. |
| SRR | Split-ring resonator. |
| VNA | Vector network analyzer. |
| RF | Radio frequency. |
| RLC | Resistor-inductor-capacitor. |
| S11 | Reflection scattering parameter. |
| S21 | Transmission scattering parameter. |
| T-resonator | Microstrip resonator shaped like the letter T. |
| L-resonator | Microstrip resonator shaped like the letter L. |
| dB | Decibels. |
| mm | Millimeters. |
| V/m | Volt per meter |
| AC | Alternating current. |
| DC | Direct current. |
| CMO | Concealed metal object. |

### DETAILED DESCRIPTION

Sensors that can detect minor faults in increasingly complex PCB metal traces are desired. Such sensors can improve PCB quality and reduce costly recalls of electronic products. The sensors of various examples enable maintaining quality standards, optimizing manufacturing processes by preventing contamination during the process of PCB manufacturing. In at least one example, using metamaterials, engineered structures with unique electromagnetic properties, can help overcome the limitations of traditional metal detectors. In at least one example, metamaterial sensors can offer enhanced sensitivity, resolution, and adaptability, making them suitable for metal detection.

In at least one example, a metal detection system based on dual resonance is provided to detect a metal block placed in the detection range of the sensor. The metal detection system can be built by placing a microstrip T-resonator or a microstrip L-resonator, and a split-ring resonator (SRR) on a planar dielectric substrate comprising two or more substantially parallel surfaces. By applying a wideband signal through the resonator in the first surface, the dual resonator apparatus resonates at a unique resonance frequency. The frequency response changes when a metal block is placed in the detection range of the sensor. A DC voltage output signal can be obtained by passing the microstrip L-resonator output through a rectifying block which is used to detect a metal object in the detection range. The use of rectifying block eliminates the necessity of using a vector network analyzer (VNA) to measure the complex output signal.

In at least one example, the metal detection system based on dual resonance incorporates a microstrip T-resonator, placed on the first surface of a planar dielectric substrate; and a split-ring resonator (SRR), placed on the second surface of a planar dielectric substrate. This system utilizes frequency response shifting when a metal block is placed in the detection range of a dual resonator device. In at least one example, the microstrip T-resonator can be replaced with a microstrip L-resonator which is coupled with a rectifying circuit block to provide a DC voltage output signal. In at least one example, the metal detection device that comprises a microstrip L-resonator does not need a vector network analyzer (VNA) apparatus to measure the change in frequency response when a metal block is placed in detection range of the dual resonator sensor. In at least one example, the DC output voltage signal response changes when a metal object is placed in the detection range of the dual resonator device. In at least one example, the metal detection system comprising a microstrip T-resonator and a microstrip L-resonator provides can be implemented on a multilayer printed circuit board (PCB). In at least one example, the metal detection device based on the dual resonance phenomenon comprises microstrip L-resonator. It can be used in an array structure in PCB fabrication or materials processing industry to detect metal blocks in the detection range of the dual resonator sensor.

In the following description, numerous details are provided to examples of the present disclosure. It will be apparent, however, to one skilled in the art, that examples of the present disclosure may be practiced without these specific details. In other instances, well-known structures and devices are shown in a block diagram form, rather than in detail, to avoid obscuring examples of the present disclosure.

Note that in the corresponding drawings of the examples, signals are represented with lines. Some lines may be thicker, to indicate more constituent signal paths, and/or have arrows at one or more ends, to indicate primary information flow direction. Such indications are not intended to be limiting. Rather, the lines are used in connection with one or more examples to facilitate easier understanding of a circuit or a logical unit. Any represented signal, as dictated by design needs or preferences, may actually comprise one or more signals that may travel in either direction, and may be implemented with any suitable type of signal scheme.

It is pointed out that those elements of the figures having the same reference numbers (or names) as the elements of any other figure can operate or function in any manner like that described but are not limited to such.

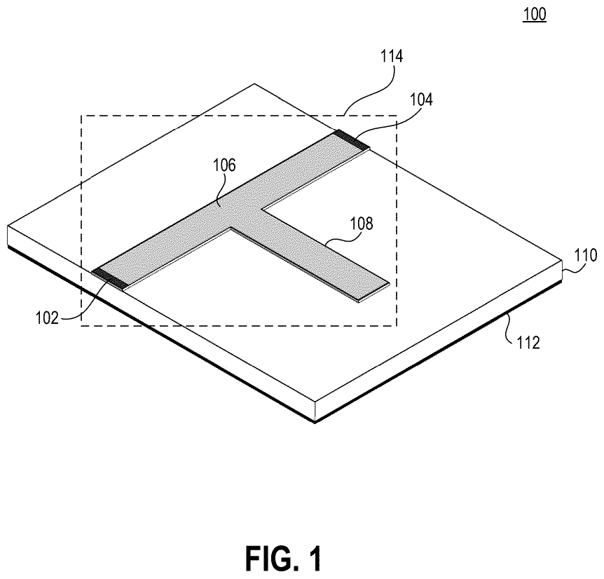

FIG. 1 is a schematic that illustrates a structure 100 of a microstrip resonator that exhibits resonance at a particular frequency, in accordance with at least one example. The microstrip resonator comprises two ports, RF port 102 and RF port 104, a transmission line 106, a stub 108, a planar dielectric substrate 110, and a ground conductor 112. Transmission line 106 and stub 108 form a microstrip T-resonator 114. In at least one example, RF ports 102 and 104 are at the ends of transmission line 106 and stub 108 may be placed substantially in the middle of transmission line 106. In at least one example, microstrip T-resonator 114 may be placed on the first surface of a planar dielectric substrate 110 and a ground conductor 112 may be placed on the second surface of planar dielectric substrate 110 for a radio frequency (RF) wave passing through RF ports 102 and 104. In at least one example, microstrip T-resonator 114 behaves like a resistor-inductor-capacitor (RLC) circuit and resonates at a particular resonance frequency that depends on the dimensions and permittivity of the material.

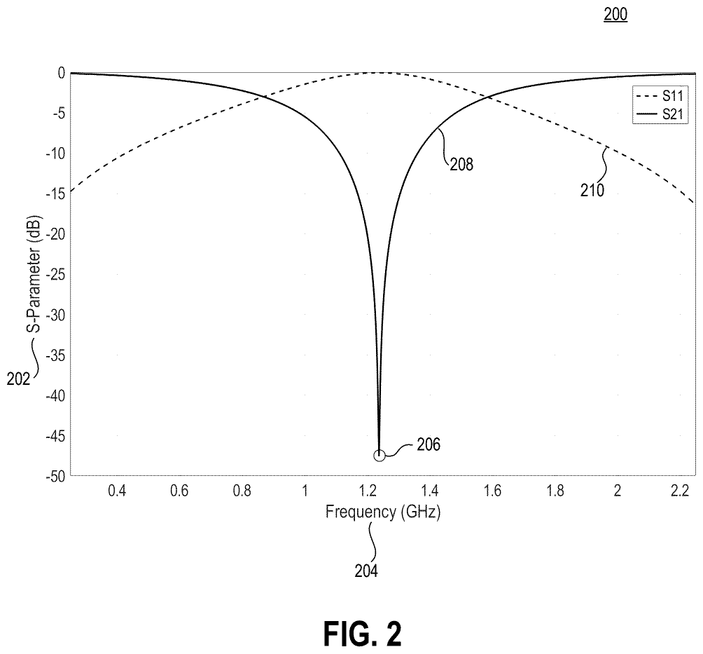

FIG. 2 is a plot 200 that illustrates scattering parameters 202 against frequency 204 of the structure 100 of FIG. 1, in accordance with at least one example. Scattering parameter S21 208 represents the transmission characteristics and scattering parameter S11 210 represents reflection characteristics. Microstrip T-resonator 114 of FIG. 1 resonates at a particular frequency and ensures S21 208 of −47 dB, and S11 210 of milli-dBs at a particular frequency 206.

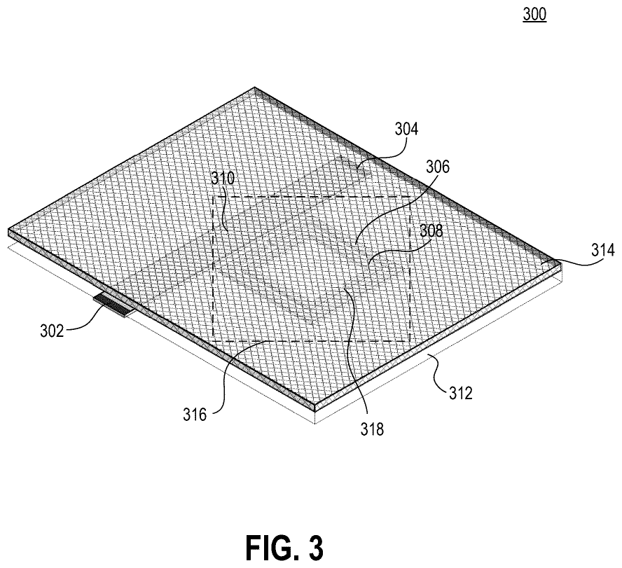

FIG. 3 is a schematic that illustrates a structure 300 of a split-ring resonator that exhibits resonance phenomenon at a particular frequency, in accordance with at least one example. Structure 300 may comprise RF ports 302 and 304 on the end of a transmission line 310, two split rings 306 and 308, planar dielectric substrate 312, and ground conductor 314. In at least one example, RF ports 302 and 304 are at the ends of transmission line 310 and split rings 306 and 308 may be placed in the second surface of planar dielectric substrate 312. Split rings 306 and 308 are rectangular rings and have different dimensions, these split rings 306 and 308 constitute split-ring resonator 316. Transmission line 310 acts as a feed line to split rings 306 and 308. In at least one example, split rings 306, 308, and transmission line 310 are placed on the second surface of planar dielectric substrate 312 and ground conductor 314 is placed on the first surface of planar dielectric substrate 312. In at least one example, split-ring resonator 316 comprising split rings 306 and 308 behave as an RLC circuit and resonate at a particular frequency that depends on the dimensions of the rectangular rings and the permittivity of the material. Split rings 306 and 308 may also comprise one or more splits therein, such as split ring 308 comprises split 318.

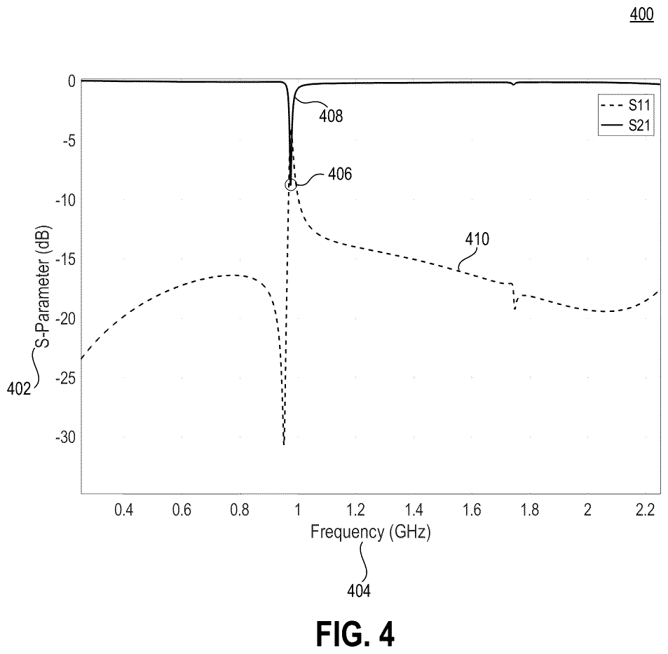

FIG. 4 is a plot 400 that illustrates S-parameter 402 against frequency 404 of structure 300 of FIG. 3, in accordance with at least one example. In at least one example, split-ring resonator 316 comprising split rings 306 and 308 may resonate at a particular resonant frequency 406 and ensure an absorption S21 408 and a reflection S11 410 for the RF signal fed to split-ring resonator 316 by transmission line 310 as illustrated in FIG. 3.

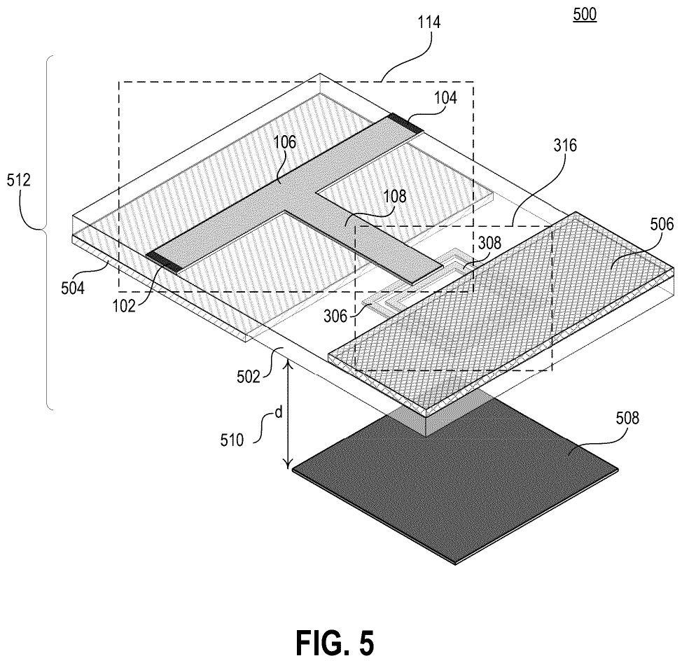

FIG. 5 is a schematic 500 that illustrates a sensor based on the dual resonance phenomenon, wherein microstrip T-resonator 114 and split-ring resonator 316 are placed on parallel surfaces of a planar dielectric substrate 502 and a metal block 508 placed in the detection range of the split-ring resonator 316, in accordance with at least one example. Dual resonator sensor 512 may comprise microstrip T-resonator 114, split-ring resonator 316, planar dielectric substrate 502, T-ground conductor 504, and S-ground conductor 506. In at least one example, microstrip T-resonator 114 may comprise RF ports 102 and 104 on the ends of transmission line 106, and stub 108 may be placed substantially in the middle of transmission line 106. In at least one example, split-ring resonator 316 may comprise two rectangular split rings 306 and 308 having different dimensions. In at least one example, microstrip T-resonator 114 is placed on the first surface of planar dielectric substrate 502 and T-ground conductor 504 is placed at the second surface of planar dielectric substrate 502, substantially overlapping the region below microstrip T-resonator 114. In at least one example, split-ring resonator 316 is placed on the second surface of planar dielectric substrate 502 such that the adjacent edge of split rings 306 and 308 substantially align with the open-ended edge of stub 108 of microstrip T-resonator 114 placed on the first surface of planar dielectric substrate 502. In at least one example, S-ground conductor 506 is placed at the first surface of planar dielectric substrate 502, substantially overlapping the region above split-ring resonator 316.

In at least one example, stub 108 is in the first surface of planar dielectric substrate 502, and it acts as a feed line to split-ring resonator 316 in the second surface of planar dielectric substrate 502. Consequently, it generates the resonance phenomenon in split-ring resonator 316 at a resonance frequency. When metal block 508 is placed in the detection range of dual resonator sensor 512 based on the dual resonance phenomenon, the frequency response exhibits a change which allows the identification of metal block 508 present at a distance 510 (d) to dual resonator sensor 512, using a vector network analyzer (VNA).

In at least one example, metal block 508 may comprise one or more conductive metallic materials, placed within the detection range of dual resonator sensor 512. Metal block 508 may have varying permittivity and may induce a perturbation in the electromagnetic field, generated by dual resonator sensor 512 of FIG. 5. Similarly, metal block 508 may also be replaced by a dielectric material, to be sensed by the said dual resonator sensor 512.

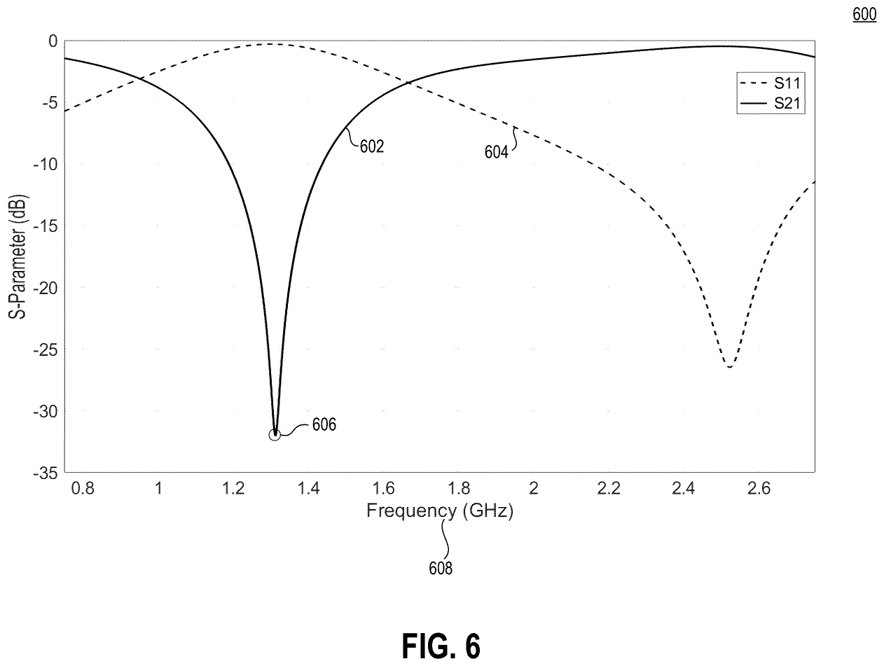

FIG. 6 is a plot 600 illustrating the transmission and reflection scattering parameter response of dual resonator sensor 512 illustrated in FIG. 5, in accordance with at least one example. An S21 response 602 represents transmittance and an S11 response 604 represents reflection in the plot 600. S21 response 602 exhibits transmittance (above 0.5) from the frequencies 0.75 GHz to 2.75 GHz as illustrated by a frequency scale 608. In at least one example, dual resonator sensor 512 of FIG. 5 may be designed for a specific resonant frequency 606 by adjusting the dimensions of microstrip T-resonator 114 and split-ring resonator 316. In at least one example, the response depends on the conductivity of the metal layer and the loss tangent (8) of the dielectric material. The response may be used to separate the metal layers in a multilayer printed circuit board (PCB), and the response may be enhanced by varying the metal or dielectric used in the PCB and their respective dimensions.

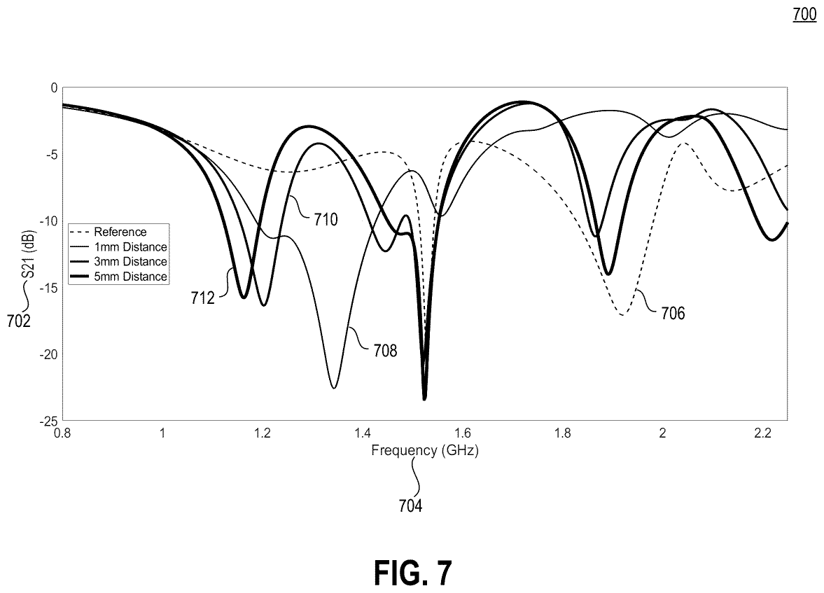

FIG. 7 is a plot 700 illustrating the S21-parameter 702 against frequency 704 of the dual resonator sensor 512 of FIG. 5, when metal block 508 is placed in proximity of 1 mm to 5 mm to dual resonator sensor 512, in accordance with at least one example. When any type of metal is outside the detection range of dual resonator sensor 512, it exhibits the response shown by curve 706, which may be used as a reference benchmark measurement. In at least one example, the S21 (dB) response of dual resonator sensor 512, when the metal is within 1 mm of its proximity, is now represented by curve 708. As the distance 510 of metal block 508 varies from 1 mm to 3 mm to 5 mm, the S21 (dB) response is represented by curves 708, 710, and 712 respectively.

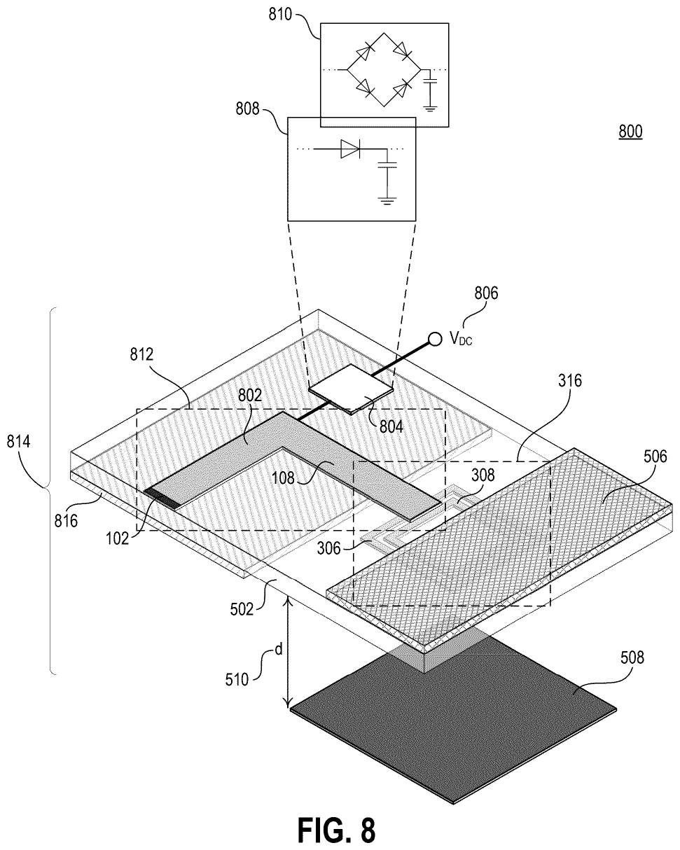

FIG. 8 is a schematic 800 that illustrates an example structure of the dual resonator device 814, wherein a transmission line 802, a stub 108, a rectifying block 804 and a split-ring resonator (SRR) 316 are placed on the parallel surfaces of planar dielectric substrate 502 to constitute a dual resonator device 814 based on the dual resonance phenomenon, in accordance with at least one example. In at least one example, dual resonator device 814 includes microstrip L-resonator 812, split-ring resonator 316, planar dielectric substrate 502, L-ground conductor 816, S-ground conductor 506, and a rectifying circuit block 804. In at least one example, microstrip L-resonator 812 includes RF port 102 on one end of a transmission line 802 and stub 108 may be placed substantially perpendicular on the other end of transmission line 802. In at least one example, split-ring resonator 316 may comprise two concentric split rings 306 and 308 having different dimensions. In at least one example, the joint of the transmission line 802 and stub 108 may be connected to the rectifying circuit block 804 to provide a DC voltage output signal VDC 806. In at least one example, rectifying circuit block 804 may comprise a half-wave rectifying circuit 808 comprising a diode and a capacitor or a full-wave bridge rectifying circuit 810 comprising four diodes and a capacitor or any other rectifying circuit as known to the ones skilled in the art.

In at least one example, microstrip L-resonator 812 is placed on the first surface of planar dielectric substrate 502, and L-ground conductor 816 is placed at the second surface of planar dielectric substrate 502. L-ground conductor 816 substantially overlaps the region below microstrip L-resonator 812. In at least one example, rectifying circuit block 804 may also be placed on the first surface of the planar dielectric substrate 502, adjacent to the microstrip L-resonator 812. In at least one example, split-ring resonator 316 is placed on the second surface of planar dielectric substrate 502 such that the adjacent edge of split rings 306 and 308 substantially align with the open-ended edge of stub 108 of the microstrip L-resonator 812 placed in the first surface of planar dielectric substrate 502. In at least one example, S-ground conductor 506 is placed at the first surface of planar dielectric substrate 502, substantially overlapping the region above split-ring resonator 316 on the second surface. In at least one example, metal block 508 may comprise one or more conductive metallic materials, placed within the detection range of the dual resonator device. In at least one example, metal block 508 may have varying permittivity and may induce a perturbation in the electromagnetic field generated by dual resonator device 814 of FIG. 8. The metal block may also be replaced by a dielectric material to sense the said dielectric material by dual resonator device 814.

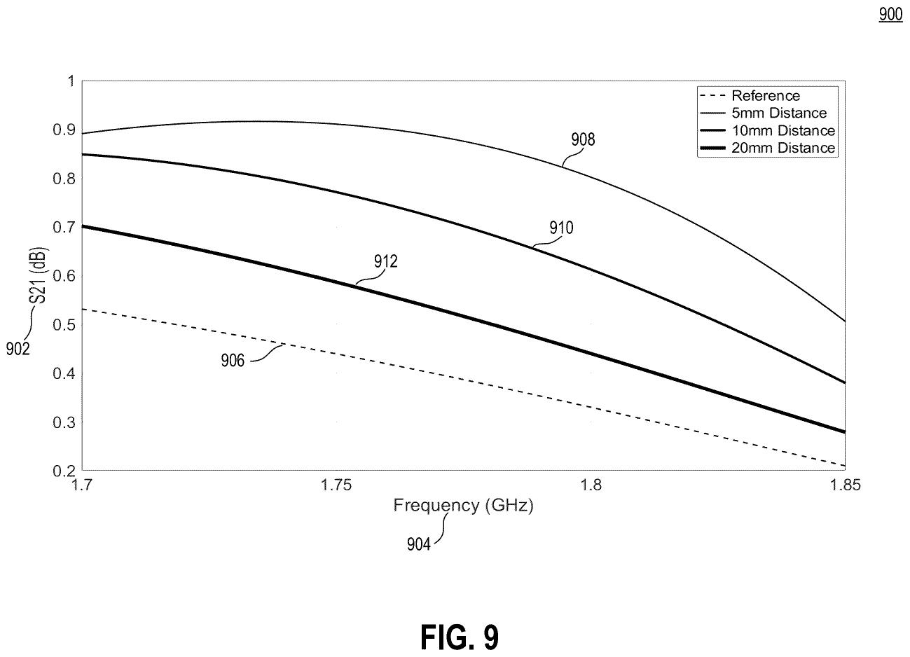

FIG. 9 is a plot 900 that illustrates an S21-parameter 902 against frequency 904 of dual resonator device 814 illustrated in FIG. 8, when metal block 508 is placed in the detection range by varying distances from 5 mm to 20 mm, in accordance with at least one example. When metal block 508 is not in the detection range of the dual resonator device 814, the dual resonator device 814 exhibits a response shown by curve 906, which may be used as a reference benchmark measurement of the frequency response. In at least one example, when metal block 508 is placed at 5 mm proximity of dual resonator device 814 illustrated in FIG. 8, the S21-parameter 902 in dB is now represented by curve 908. As distance 510 of metal block 508 increases from 5 mm to 10 mm to 20 mm, S21-parameter 902 in dB is represented by curves 908, 910, and 912 at the corresponding distances, respectively. This shows a shift in scattering parameters. In at least one example, as distance 510 between metal block 508 and dual resonator device 814 in FIG. 8 increases, S21-parameter 902 in dB may approach the reference benchmark measurement curve 906 of the frequency response.

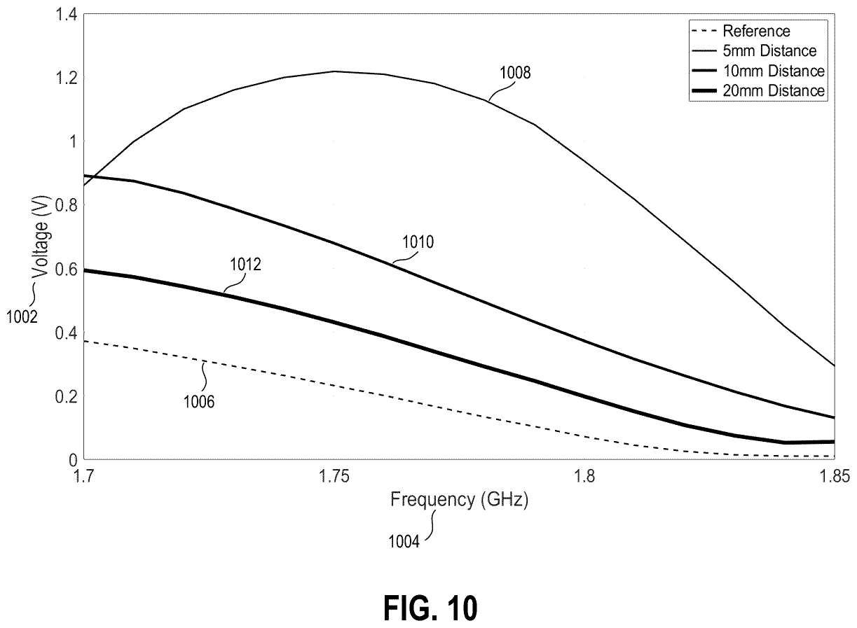

FIG. 10 is a plot 1000 illustrating a DC voltage output 1002 against frequency 1004 of dual resonator device 814 illustrated in FIG. 8, when metal block 508 is placed in the detection range by varying distances from 5 mm to 20 mm, in accordance with at least one example. In at least one example, when metal block 508 is outside the detection range of dual resonator device 814, it exhibits a DC voltage response shown by curve 1006, which may be used as a reference benchmark measurement for the DC voltage response. In at least one example, when metal block 508 is placed at 5 mm proximity of dual resonator device 814, DC voltage output 1002 of dual resonator device 814 is now represented by curve 1008 that shows a shift in DC voltage response. As distance 510 of metal block 508 increases from 5 mm to 10 mm to 20 mm, DC voltage output 1002 of dual resonator device 814 at respective distances are represented by curves 1008, 1010, and 1012 respectively, showing a shift in DC voltage. In at least one example, as distance 510 between dual resonator device 814 in FIG. 8 and metal block 508 increases, DC voltage output 1002 against the frequency 1004 may approach the benchmark reference DC voltage curve 1006. In at least one example, the use of the rectifying circuit block 804 to obtain a DC voltage signal may replace the need of measuring the shift in scattering parameters using a vector network analyzer (VNA).

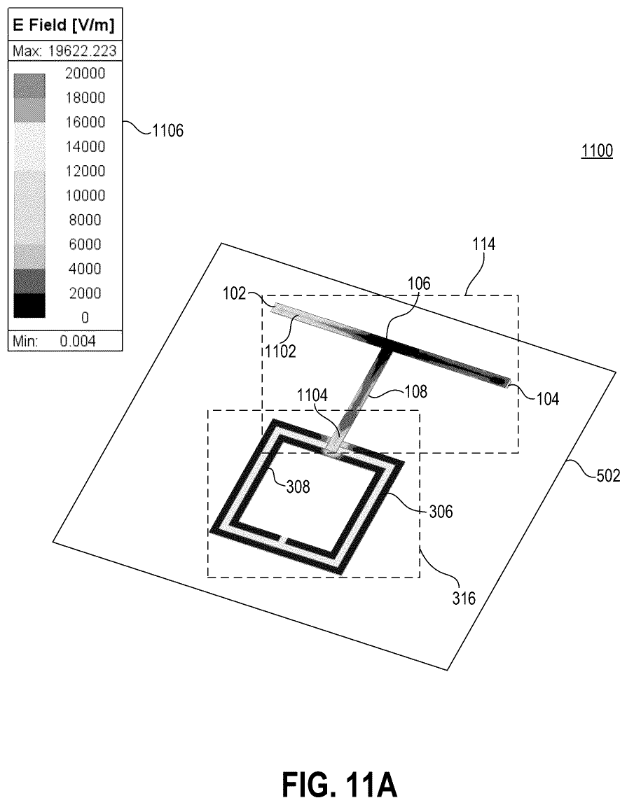

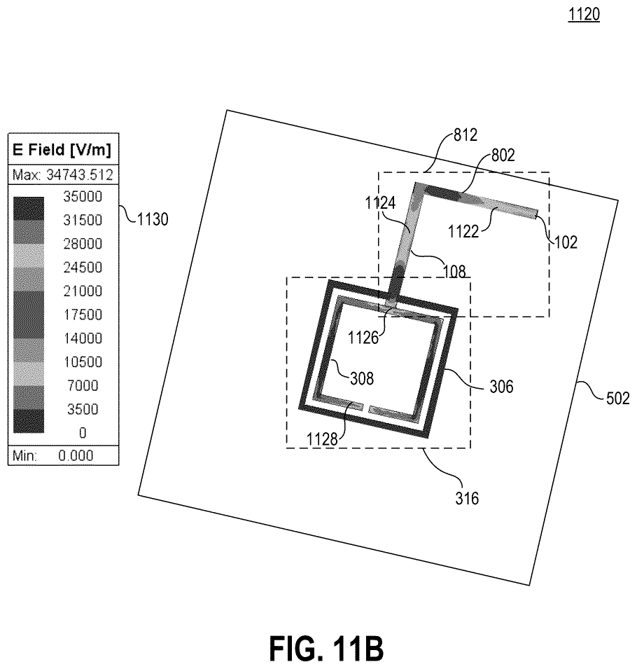

FIG. 11A is a schematic 1100 that illustrates an electric field magnitude plot of dual resonator sensor 512 illustrated in FIG. 5, when an RF signal is applied on RF port 102, in accordance with at least one example. In at least one example, dual resonator sensor 512 comprising the microstrip T-resonator 114 including RF ports 102 and 104, transmission line 106, and stub 108, and split-ring resonator 316 including split rings 306 and 308 is placed on planar dielectric substrate 502. The RF wave is absorbed at RF port 102 and the field is distributed in microstrip T-resonator 114 and split-ring resonator 316. In at least one example, at the resonant frequency, the curve plot reveals an intensity of near 20000 V/m, particularly around regions 1102 and 1104. The variation in intensity of the wave energy is tabulated in table 1106.

FIG. 11B is a schematic 1120 that illustrates an electric field magnitude plot of dual resonator device 814 of FIG. 8, when an RF signal is applied at RF port 102, in accordance with at least one example. In at least one example, dual resonator device 814 comprising microstrip L-resonator 812 including RF port 102, transmission line 802, and stub 108, and split-ring resonator 316 including split rings 306 and 308 is placed on planar dielectric substrate 502. The RF wave is absorbed at RF port 102 and the wave energy is distributed in microstrip L-resonator 812 and split-ring resonator 316. In at least one example, at the resonant frequency, the plot reveals intensity of approximately 35000 V/m, particularly around regions 1122, 1124, 1126, and 1128. The variation in intensity of the field is tabulated in table 1130.

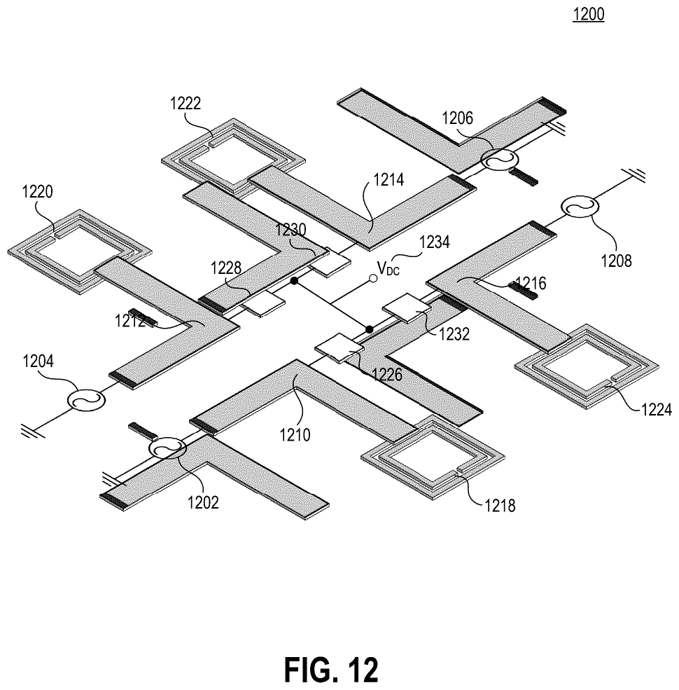

FIG. 12 is a schematic that illustrates an example multi-resonator structure 1200 of dual resonator device 814, wherein four distinct dual resonator devices 814 are arranged and connected in an array structure, in accordance with at least one example. In at least one example, multi-resonator structure 1200 comprises RF sources modeled as voltage sources 1202, 1204, 1206, and 1208, microstrip L-resonators 1210, 1212, 1214, and 1216, split-ring resonators 1218, 1220, 1222, and 1224, rectifying circuit blocks 1226, 1228, 1230, and 1232, and cumulative DC voltage output signal VDC 1234. In at least one example, the individual DC voltage outputs from rectifying circuit blocks 1226, 1228, 1230, and 1232 may be coupled together to obtain a cumulative DC voltage output signal Vpc 1234. In at least one example, multi-resonator structure 1200 may increase the combined range and cumulative precision of multi-resonator structure in comparison to a single dual resonator device 814 of FIG. 8. Individual output of the sensors may also be used for any application as necessary.

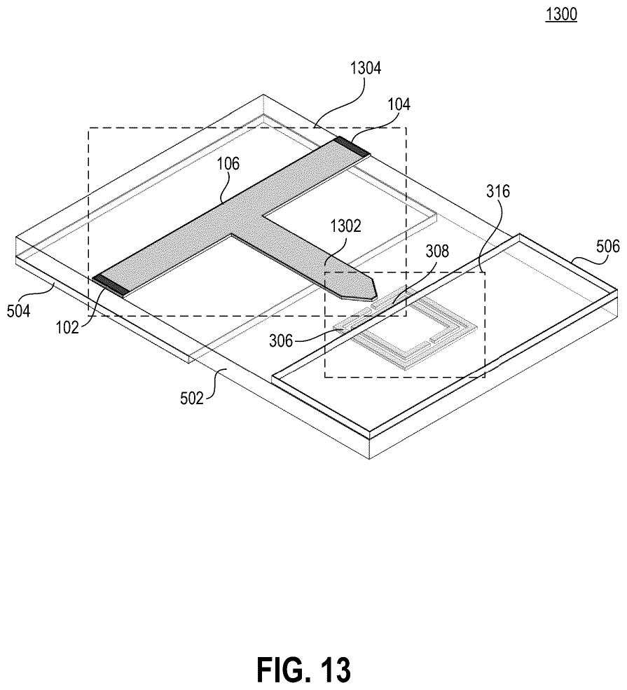

FIG. 13 is a schematic that illustrates an example structure 1300 of dual resonator sensor 512 with a chamfered stub 1302 of a microstrip T-resonator 1304, wherein microstrip T-resonator 1304 and split-ring resonator 316 are placed on the parallel surfaces of a planar dielectric substrate 502 to constitute structure 1300 of the dual resonator sensor, in accordance with at least one example. In at least one example, microstrip T-resonator 1304 comprises RF ports 102 and 104 on the ends of transmission line 106 and a stub 1302 may be placed substantially in the middle of transmission line 106. The open-end of stub 1302 is chamfered but may not be taken limiting and can be of other shapes like filleted or rounded as well. In at least one example, split-ring resonator 316 may comprise two concentric split rings 306 and 308 having different dimensions. In at least one example, microstrip T-resonator 1304 is placed on the first surface of planar dielectric substrate 502 and T-ground conductor 504 is placed at the second surface of planar dielectric substrate 502, substantially overlapping the region below microstrip T-resonator 1304. In at least one example, split-ring resonator 316 is placed on the second surface of planar dielectric substrate 502, such that the adjacent edge of split rings 306 and 308 substantially align with the open-ended edge of stub 1302 of microstrip T-resonator 1304, which is placed in the first surface of planar dielectric substrate 502. In at least one example, S-ground conductor 506 is placed at the first surface of the planar dielectric substrate 502, substantially overlapping the region above split-ring resonator 316.

In at least one example, stub 1302, in the first surface of planar dielectric substrate 502, acts as a feed line to split-ring resonator 316, wherein the chamfering of the open-end of stub 1302 ensures a field intensity higher than 20000 V/m of the field, as known to the ones skilled in the art. This ensures improved performance of the resonator.

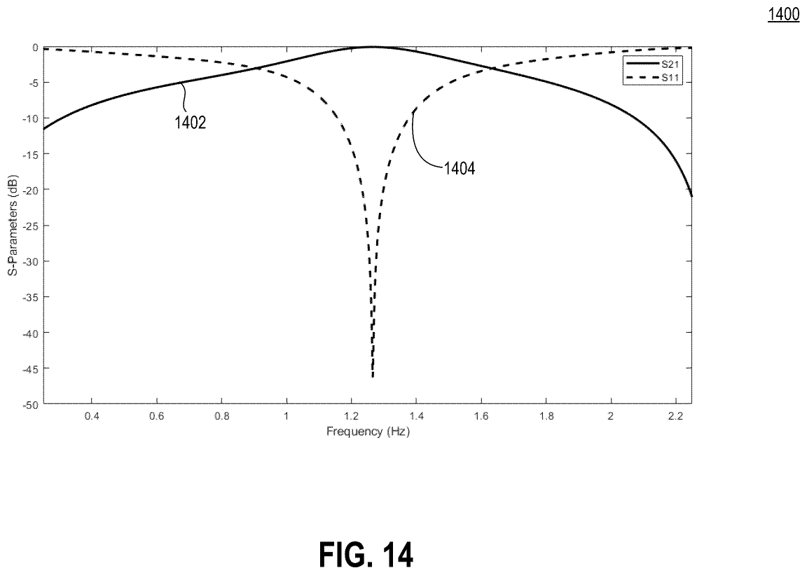

FIG. 14 is a plot 1400 that illustrates the scattering parameters of structure 1300 (e.g., dual resonator sensor of FIG. 13), in accordance with at least one example. Plot 1400 exhibits the transmission scattering parameter S21 1402 and reflection scattering parameter S11 1404. Plot 1400 displays significant improvement with a 45 dB isolation at the resonant frequency of the dual resonator sensor of FIG. 13, in comparison to plot 600 with an isolation of 32 dB, in accordance with at least one example. Chamfering of stub 1302 may ensure fields of more than 20000 V/m, in accordance with at least one example.

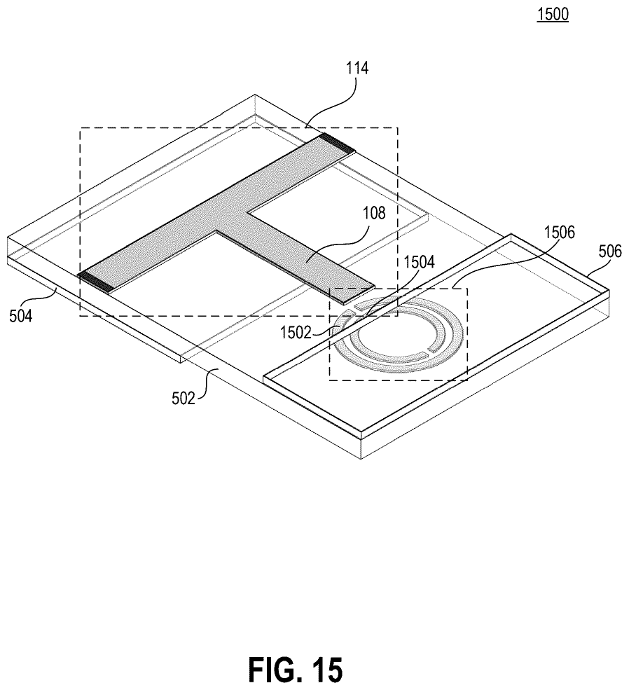

FIG. 15 is a schematic that illustrates an example structure 1500 of dual resonator sensor 512, wherein circular rings 1502 and 1504 constitute split-ring resonator 1506, in accordance with at least one example. In at least one example, structure 1500 comprises microstrip T-resonator 114 on the first surface of planar dielectric substrate 502, wherein the stub 108 of microstrip T-resonator 114 is configured to feed circular split rings 1502 and 1504 of split-ring resonator 1506 placed on the second surface of planar dielectric substrate 502. T-ground conductor 504 overlaps microstrip T-resonator 114 and S-ground conductor 506 overlaps split-ring resonator 1506. The shape of rings 1502 and 1504 of split-ring resonator 1506 is not taken to be limiting rather any configuration suitable for the metal detection application may be used.

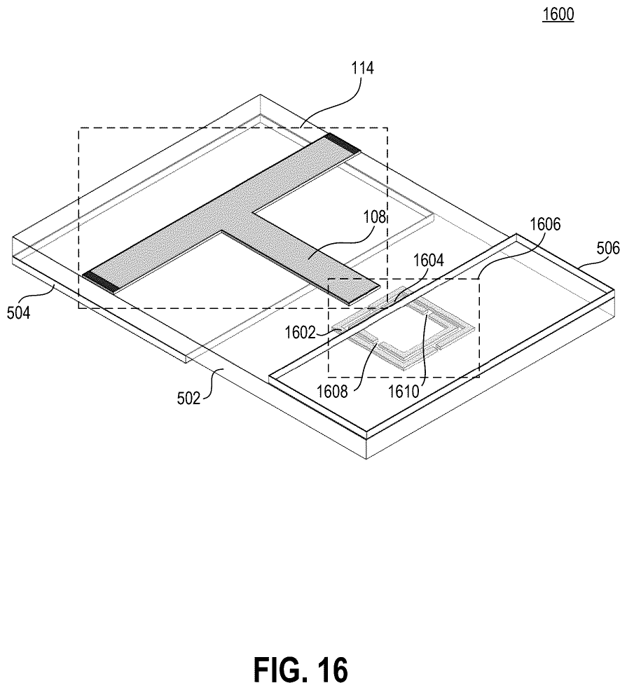

FIG. 16 is a schematic that illustrates an example structure 1600 of the dual resonator sensor, wherein rings 1602 and 1604 of split-ring resonator 1606 include more than one split such as splits 1608 and 1610 in ring 1604, in accordance with at least one example. Structure 1600 comprises microstrip T-resonator 114 on the first surface of planar dielectric substrate 502, wherein stub 108 of microstrip T-resonator 114 is configured to feed the split rings 1602 and 1604 of the split-ring resonator 1606 placed on the second surface of planar dielectric substrate 502. T-ground conductor 504 overlaps microstrip T-resonator 114 and S-ground conductor 506 overlaps split-ring resonator 1606. The shape of split rings 1602 and 1604 of split-ring resonator 1606 or the number of splits therein is not taken to be limiting rather that can work for the metal detection application may be used.

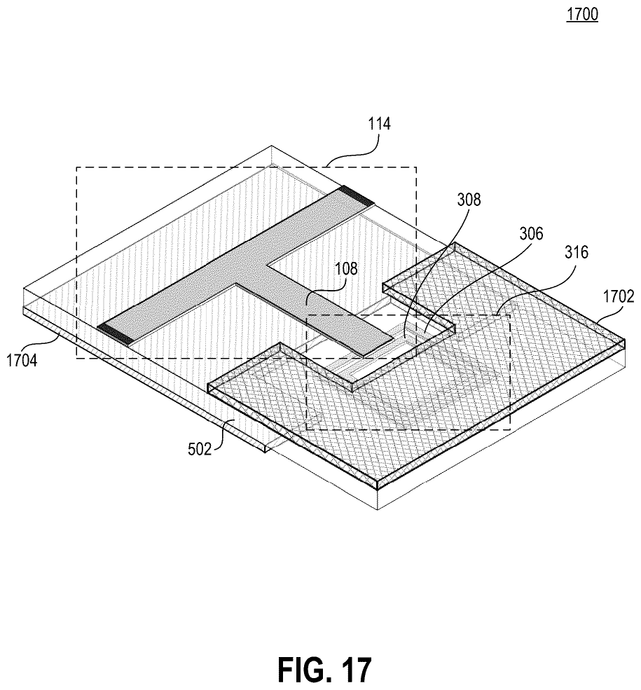

FIG. 17 is a schematic that illustrates an example structure 1700 of the dual resonator sensor, wherein the ground conductors; S-ground conductor 1702, and T-ground conductor 1704 overlap, in accordance with at least one example. Structure 1700 comprises microstrip T-resonator 114 on the first surface of planar dielectric substrate 502, wherein stub 108 of microstrip T-resonator 114 is configured to feed split rings 306 and 308 of split-ring resonator 316 placed on the second surface of planar dielectric substrate 502. S-ground conductor 1702 for split-ring resonator 316 is placed on the first surface of the planar dielectric substrate 502, wherein the widths of ground conductor 1702 extends around stub 108 of microstrip T-resonator 114. Similarly, T-ground conductor 1704 for microstrip T-resonator 114 is placed on the second surface of planar dielectric substrate 502, wherein the widths of ground conductor 1704 extends around split ring 306 of split-ring resonator 316 such that one or more widths of ground conductors 1702 and 1704 substantially overlap. The thickness of ground conductors 1702 and 1704 is limited by the thickness of the metal layers of the printed circuit board. Ground conductors 1702 and 1704 are shown thicker in FIG. 17 for a better visualization only.

The example structures 1300, 1500, 1600, and 1700 of FIG. 13, FIG. 15, FIG. 16, and FIG. 17, respectively, represent the different configurations and shapes that the microstrip T-resonator or the split-ring resonator may comprise suitable for application. But these shapes and configurations are not taken to be limiting but are illustrated for the purpose of explanation only and may be used as a combination thereof as well.

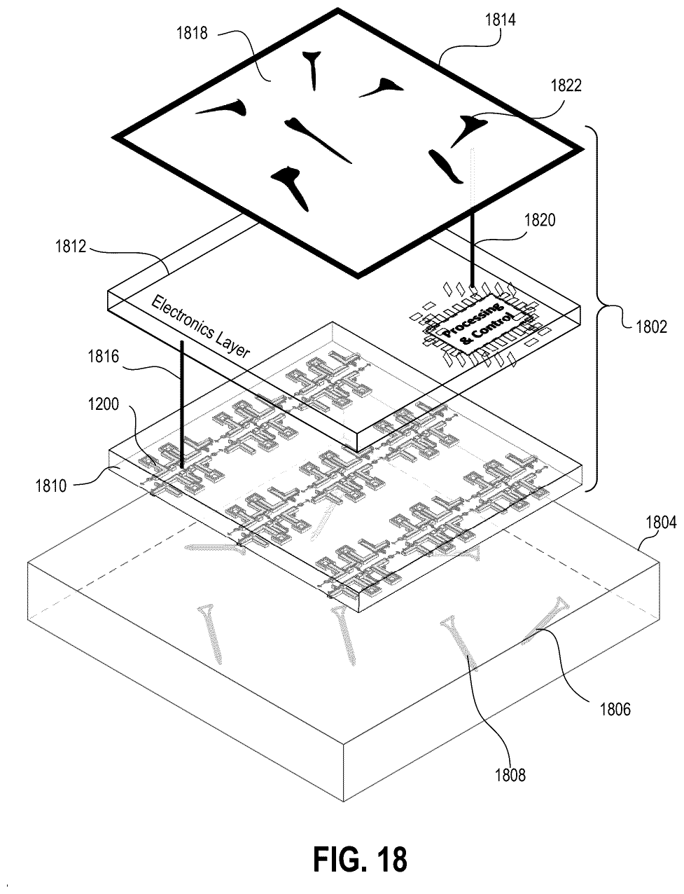

FIG. 18 is a schematic 1800 that illustrates the metal detection scanner apparatus 1802, which is used to scan for a metal object 1804, which is typically concealed and not visible to the human eye or camera. The metal detection scanner apparatus must detect metal nails 1806 and 1808, in accordance with at least one example. The metal detection scanner apparatus 1802 comprises three layers: (1) a dual resonator sensor layer 1810, (2) an electronics layer 1812, (3) and a display layer 1814, in accordance with at least one example. Object 1804 may be a wooden plank or a wall that has concealed metal objects (CMOs) such as metal nails 1806, 1808, or other metal objects such as pipes, wires etc. Since the concealed metal objects might create a hazard when object 1804 is processed. Metal detection scanner apparatus 1802 comprises a sensor layer 1810 which comprises of an array of multi-resonator structure 1200 of FIG. 12. These structures are managed by electronics layer 1812 through vias such as via 1816. The retrieved data from the sensors is processed by the same layer 1812 and displayed on screen 1818 of display layer 1814 through vias such as via 1820. Depending on the sensor sensitivity and integration, the scanned image will display the concealed metal objects such as one or more detected metal nails on a screen as image 1822.

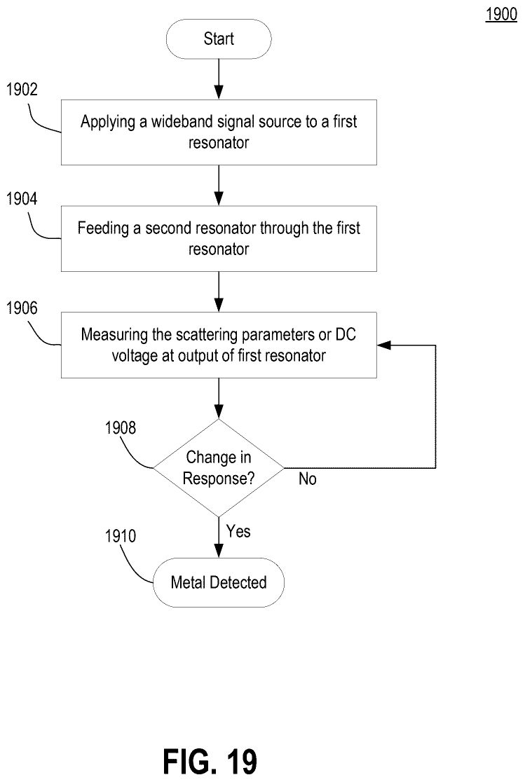

FIG. 19 is a flowchart 1900 that illustrates a method of a dual resonator device metal detection, in accordance with at least one example. The metal detection method starts at block 1902, wherein a wideband signal source is applied to a port of a first resonator. The first resonator begins to resonate and an open-end of a stub of the first resonator emits fields necessary to feed a second resonator at block 1904, wherein the second resonator begins to resonate. The second resonator is electrically isolated from the first resonator. At block 1906 the scattering parameters a DC output voltage from the rectifying block connected to the first resonator is measured. If a metal object is placed in the detection range of the dual resonator device, the scattering parameters, or the DC output voltage shifts. Block 1908 is a decision step, wherein the response is analyzed for any changes. If the response is substantially shifted, whether the scattering parameters or the DC output voltage, block 1910 indicates the detection through a signal or a display, as known to the ones skilled in the art. If the metal is not detected, the method repeats from block 1906 to proceed the detection.

Throughout specification, and in claims, “connected” may generally refer to a direct connection, such as electrical, mechanical, or magnetic connection between things that are connected, without any intermediary devices.

Here, “coupled” may generally refer to a direct or indirect connection, such as a direct electrical, mechanical, or magnetic connection between things that are connected or an indirect connection, through one or more passive or active intermediary devices.

Here, “adjacent” may generally refer to a position of a thing being next to (e.g., immediately next to or close to with one or more things between them) or adjoining another thing (e.g., abutting it).

Here, “circuit” or “module” may generally refer to one or more passive and/or active components that are arranged to cooperate with one another to provide a desired function.

Here, “resonator” may generally refer to a passive component consisting of a conductive strip patterned on a dielectric substrate. These resonators are designed to generate, select, or filter specific frequencies within microwave or RF circuits.

Here, “ground conductor” may generally refer to a conductive layer typically located beneath the microstrip structure that provides a return path for the electromagnetic fields generated by the resonator. This ground conductor helps to establish the electrical characteristics of the microstrip structure and influence the resonant frequency and performance of the resonator.

Here, “planar dielectric substrate” may generally refer to a flat, typically thin, insulating material used as a base for constructing microstrip circuits and/or components with two substantially parallel surfaces. In the context of microstrip resonators, this substrate serves as the foundation surface on which the conductive traces and other components are deposited or etched. It provides mechanical support, electrical isolation, and defines the physical dimensions and characteristics of the microstrip resonator.

Here, “detection range” may generally refer to the operational range within which a sensing device or system can accurately detect and measure a target or signal and more particularly to the range in which a dual resonator sensor or dual resonator device may exhibit a measurement response shift, when the object is within the operational range.

Here, “first surface”, “second surface” may generally refer to the surfaces relative to a reference point or direction and more particularly to two parallel surfaces of the planar dielectric substrate, each of which contains metal depositions to form a printed circuit board.

Here, “same frequency” may generally refer to the condition where two resonators exhibit oscillation rates or natural frequencies that are sufficiently close to one other in the frequency band. While not necessarily pinpoint exact, “same frequency” denotes that both systems resonate at frequencies that are within an acceptable tolerance or margin of each other.

Here, “scattering parameters” may generally refer to a set of mathematical representations commonly used in electrical engineering and RF systems to characterize the behavior of linear electrical networks, such as resonators, filters, and transmission lines, in terms of signal propagation and interaction.

Here, “frequency response” may generally refer to the characteristic behavior of a system or device across a range of frequencies, as described by its scattering parameters or DC output voltage.

Here, “shifting of response” may generally refer to the displacement or alteration in the behavior or characteristics of a system's output relative to changes in its input or operating conditions and more particularly to the change in the output of the dual-resonator sensor's DC voltage or scattering parameters when an object is within its detection range.

Here, “microstrip T-resonator” may generally refer to a specific type of microstrip resonator configuration, particularly characterized by a resonator structure shaped like the letter “T” on a planar dielectric substrate. This configuration forms a resonant structure with distinct electrical properties, enabling it to manipulate specific frequencies within microwave or RF circuits.

Here, “T-ground conductor” may generally refer to a conductive layer typically located beneath the microstrip T-resonator that provides a return path for the electromagnetic fields generated by the microstrip T-resonator. This ground conductor helps to establish the electrical characteristics of the microstrip T-resonator and influences the resonant frequency and performance of the microstrip T-resonator. This ground conductor may also be used for the microstrip L-resonator.

Here, “L-ground conductor” may generally refer to a conductive layer typically located beneath the microstrip L-resonator that provides a return path for the electromagnetic fields generated by the microstrip L-resonator. This ground conductor helps to establish the electrical characteristics of the microstrip L-resonator and influences the resonant frequency and performance of the microstrip L-resonator.

Here, “open-ended stub” may generally refer to a short length of transmission line or conductor used in microstrip resonator configurations and more particularly to a microstrip line with one end that is disconnected or open, called open-end. In the context of microstrip resonators, stubs are often employed to modify the electrical characteristics of the resonator, such as impedance matching, frequency tuning, or bandwidth adjustment.

Here, “microstrip L-resonator” may generally refer to a specific type of microstrip resonator configuration and more particularly to a resonator that consists of a conductive trace shaped in the form of the letter “L” on a planar dielectric substrate. This configuration creates a resonant structure with specific electrical properties, allowing it to generate, select, or filter specific frequencies in microwave or RF circuits.

Here, “S-ground conductor” may generally refer to a conductive layer typically located beneath the split-ring resonator that provides a return path for the electromagnetic fields generated by the split-ring resonator. This ground conductor helps to establish the electrical characteristics of the split-ring resonator and influences the resonant frequency and performance of the split-ring resonator.

Here, “multi-resonator device” may generally refer to a device comprising multiple resonant structures or elements designed to exhibit resonant behavior at distinct frequencies or same frequencies.

Here, “rectifying block” may generally refer to a component within a system designed to convert alternating current (AC) signals into direct current (DC) signals and more particularly to a block that is used to convert input alternating current (AC) signals from the microstrip L-resonator into direct current (DC) output signals.

Here, “split-ring resonator” may generally refer to a type of resonant structure used in microwave and RF engineering. It typically consists of a ring-shaped conductor that is split at one or more points, often forming a small gap or slot.

Here, “split” may generally refer to the intentional division of the rings in the split-ring resonator at one or more points, often resulting in the formation of a small gap or slot.

Here, “width” may generally refer to the areas of the ground conductor that extend horizontally from the main body of the conductor. These extensions contribute to the overall surface area of the ground conductor, enabling effective dissipation of electrical currents and minimizing electromagnetic interference (EMI) in electronic circuits and systems. These widths may extend around existing traces of conductors to prevent short-circuit.

Here, “wideband signal source” generally refers to a device capable of generating signals covering a broad range of frequencies. In the context of microstrip resonators, a wideband signal source could be an instrument or module designed to produce RF or microwave signals with a wide frequency spectrum.

Here, “vector network analyzer” may generally refer to a sophisticated electronic instrument used to measure the electrical characteristics of RF (radio frequency) and microwave components, circuits, and systems. In the context of microstrip resonators, a vector network analyzer (VNA) plays a crucial role in characterizing their performance by analyzing parameters such as impedance, scattering parameters (S-parameters), and frequency response over a specified range.

Here, “electrical isolation” may generally refer to a state achieved by separating electrical circuits or components to prevent unwanted interaction or interference and more particularly to the use of insulating materials or barriers such as the planar dielectric substrate to ensure that electrical signals or currents do not flow between isolated components or circuits.

Here, “concentric” may generally refer to a geometric arrangement where multiple shapes or structures share a common center point, axis, or origin, regardless of whether they are circular, rectangular, or polygonal and more particularly to the split-rings of the split-ring resonator to share a common center.

Here, “transmittance” may generally refer to the measure of the ability of a sensor or device to allow the passage signals through it.

Here, “chamfered stub” may generally refer to a stub with one or more edges or corners that have been cut or shaped at an angle, resulting in a beveled surface for efficient performance and more particularly to the open-ended stub of the microstrip T-resonator or the microstrip L-resonator that has angled edges at the open-end.

Here, “proximity” may generally refer to a proximity ranging from a few millimeters (0.1 mm minimum) to a few hundred millimeters (100 mm to 200 mm).

Here, “enhanced sensitivity” may generally refer to improved performance of dual resonator sensors in terms of detection sensitivity.

Here, “electronics layer” may generally refer to a layer inside a device that contains the analog/digital circuitry/components necessary to operate such a device.

Here, “concealed metal object” may generally refer to a metal object that is buried inside a wall or plank and hence invisible to the naked eye such as nails inside a wooden plank or wires/pipes inside a wall.

Here, “dual resonator scanner” or “dual resonator device” may generally refer to an electronic instrument used to detect deformities or concealed metal objects, and more particularly to a scanner that consists of dual resonator sensors that assist the detection of such concealed metal objects.

Here, “signal” may generally refer to at least one current signal, voltage signal, magnetic signal, or data/clock signal. Here, meaning of “a,” “an,” and “the” include plural references. Here, meaning of “in” includes “in” and “on”.

Here, “scaling” may generally refer to converting a design (schematic and layout) from one process technology to another process technology and subsequently being reduced in layout area. Here, “scaling” may generally refer to downsizing layout and devices within same technology node. Here, “scaling” may also generally refer to adjusting (e.g., slowing down or speeding up—e.g., scaling down, or scaling up respectively) of a signal frequency relative to another parameter, for example, power supply level.

Here, terms “substantially,” “close,” “approximately,” “near,” and “about,” generally refer to being within +/−10% of a target value. For example, unless otherwise specified in explicit context of their use, terms “substantially equal,” “about equal” and “approximately equal” mean that there is no more than incidental variation between among things so described. In at least one embodiment, such variation is typically no more than +/−10% of a predetermined target value.

Unless otherwise specified use of ordinal adjectives “first,” “second,” and “third,” etc., to describe a common object, merely indicate that different instances of like objects are being referred to and are not intended to imply that objects so described must be in a given sequence, either temporally, spatially, in ranking or in any other manner.

Here, “left,” “right,” “front,” “back,” “top,” “bottom,” “over,” “under,” and like in description and in claims, if any, are used for descriptive purposes and not necessarily for describing permanent relative positions. In at least one embodiment, “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. In at least one embodiment, these terms are employed herein for descriptive purposes only and predominantly within context of a device z-axis and therefore may be relative to an orientation of a device. In at least one embodiment, a first material “over” a second material in context of a figure provided herein may also be “under” second material if device is oriented upside-down relative to context of figure provided. In context of materials, one material disposed over or under another may be directly in contact or may have one or more intervening materials. Moreover, one material disposed between two materials may be directly in contact with two layers or may have one or more intervening layers. In at least one embodiment, a first material “on” a second material is in direct contact with that second material. Similar distinctions are to be made in context of component assemblies.

Here, “between” may be employed in context of z-axis, x-axis, or y-axis of a device. In at least one embodiment, a material that is between two other materials may be in contact with one or both of those materials, or may be separated from both of other two materials by one or more intervening materials. In at least one embodiment, a material “between” two other materials may therefore be in contact with either of other two materials, or may be coupled to other two materials through an intervening material. In at least one embodiment, a device that is between two other devices may be directly connected to one or both of those devices, or may be separated from both of other two devices by one or more intervening devices.

Reference in specification to “an embodiment,” “one embodiment,” “in at least one embodiment,” “some embodiments,” or “other embodiments” means that a particular feature, structure, or characteristic described in connection with embodiments is included in at least some embodiments, but not necessarily all embodiments. Various appearances of “an embodiment,” “one embodiment,” “in at least one embodiment,” or “some embodiments” are not necessarily all referring to same embodiments. If specification states a component, feature, structure, or characteristic “may,” “might,” or “could” be included, that particular component, feature, structure, or characteristic is not required to be included. If specification or claim refers to “a” or “an” element, that does not mean there is only one of elements. If specification or claims refer to “an additional” element, that does not preclude there being more than one of additional elements.

Furthermore, particular features, structures, functions, or characteristics may be combined in any suitable manner in one or more embodiments. For example, a first embodiment may be combined with a second embodiment anywhere particular features, structures, functions, or characteristics associated with two embodiments are not mutually exclusive.

While at least one embodiment has been described in conjunction with specific embodiments thereof, many alternatives, modifications and variations of such embodiments will be apparent to those of ordinary skill in the art considering description herein. At least one embodiment is intended to embrace all such alternatives, modifications, and variations as to fall within broad scope of appended claims.

In addition, well-known power/ground connections to integrated circuit (IC) chips and other components may or may not be shown within presented figures, for simplicity of illustration and discussion, and so as not to obscure any embodiment. Further, arrangements may be shown in block diagram form to avoid obscuring any embodiment, and in view of the fact that specifics with respect to implementation of such block diagram arrangements are dependent upon the platform within which an embodiment is to be implemented (e.g., such specifics should be well within purview of one skilled in art). Where specific details (e.g., circuits) are set forth to describe example embodiments of disclosure, it should be apparent to one skilled in art that disclosure can be practiced without, or with variation of, these specific details. Description of an embodiment is thus to be regarded as illustrative instead of limiting.

In at least one embodiment, structures described herein can also be described as method(s) of forming those structures or apparatuses, and method(s) of operation of these structures or apparatuses. Following examples are provided that illustrate at least one embodiment. An example can be combined with any other example. As such, at least one embodiment can be combined with at least another embodiment without changing scope of an embodiment.

Example 1 is an apparatus of a dual resonator device comprising: a planar dielectric substrate configured to provide electrical insulation; a microstrip L-resonator on a first surface of the planar dielectric substrate, wherein the microstrip L-resonator includes: a transmission line; and an open-ended stub substantially perpendicular to the transmission line, wherein the open-ended stub is connected to one end of the transmission line; an L-ground conductor on a second surface of the planar dielectric substrate, wherein the L-ground conductor substantially overlaps with the microstrip L-resonator; a split-ring resonator on the second surface of the planar dielectric substrate, wherein the split-ring resonator includes: one or more split rings, wherein each split ring of the one or more split rings includes one or more splits; an S-ground conductor on the first surface of the planar dielectric substrate, wherein the S-ground conductor substantially overlaps with the split-ring resonator; and a rectifying block configured to rectify AC signals from the microstrip L-resonator into DC output signals.

Example 2 is an apparatus according to any examples herein, in particular example 1, wherein the microstrip L-resonator includes: one or more open-ended stubs, wherein each open-ended stub of the one or more open-ended stubs is configured to feed the split-ring resonator.

Example 3 is an apparatus according to any examples herein, in particular example 1, wherein the microstrip L-resonator and the split-ring resonator are configured to resonate at a same frequency.

Example 4 is an apparatus according to any examples herein, in particular example 1, wherein each split ring of the one or more split rings of the split-ring resonator has one of: polygonal shape; circular shape; or any combination thereof.

Example 5 is an apparatus according to any examples herein, in particular example 1, wherein the planar dielectric substrate constitutes one or more dielectric materials.

Example 6 is an apparatus according to any examples herein, in particular example 1, wherein the open-ended stub of the microstrip L-resonator has one of: curved shape; tapered shape; rectangular shape; hexagonal shape; or any combination thereof.

Example 7 is an apparatus according to any examples herein, in particular example 1, wherein the resonant frequency of the microstrip L-resonator or the resonant frequency of the split-ring resonator is in microwave, millimeter wave, or terra hertz communication bands.

Example 8 is an apparatus according to any examples herein, in particular example 1, wherein one or more surfaces of the L-ground conductor substantially overlap with one or more surfaces of the S-ground.

Example 9 is an apparatus of a dual resonator sensor comprising: a planar dielectric substrate configured to provide electrical insulation; a first resonator on a first surface of the planar dielectric substrate; a first ground conductor on a second surface of the planar dielectric substrate, wherein the first ground conductor substantially overlaps with the first resonator; a second resonator on the second surface of the planar dielectric substrate, wherein the first resonator is configured to feed the second resonator; and a second ground conductor on the first surface of the planar dielectric substrate, wherein the second ground conductor substantially overlaps with the second resonator.

Example 10 is an apparatus according to any examples herein, in particular example 9, wherein the first resonator is a microstrip T-resonator or a microstrip L-resonator, wherein the microstrip T-resonator or the microstrip L-resonator includes: a transmission line; and an open-ended stub substantially perpendicular to the transmission line, wherein the open-ended stub is connected to the middle or the end of the transmission line, wherein an open end of the open-ended stub is configured to feed the second resonator.

Example 11 is an apparatus according to any examples herein, in particular example 9, wherein the second resonator is a split-ring resonator comprising: one or more split rings, wherein each split ring of the one or more split rings includes one or more splits, wherein each split ring of the one or more split rings has one of: polygonal shape; circular shape; or any combination thereof.

Example 12 is an apparatus according to any examples herein, in particular example 9, wherein the first resonator and the second resonator are configured to resonate at a same frequency.

Example 13 is an apparatus according to any examples herein, in particular example 9, wherein the planar dielectric substrate constitutes one or more dielectric materials.

Example 14 is an apparatus according to any examples herein, in particular example 9, wherein one or more surfaces of the first ground conductor substantially overlap with one or more surfaces of the second ground conductor.

Example 15 is a method of metal detection using a dual resonator device, the method comprising: applying a wideband signal source to a first resonator, wherein the wideband signal source is configured to sweep a signal within a frequency range, wherein resonant frequency of the first resonator lies within the frequency range of the wideband signal source; feeding a second resonator through the first resonator, wherein the second resonator is electrically isolated from the first resonator; and detecting a metal by sensing a perturbation in scattering parameters or DC response from the first resonator.

Example 16 is a method according to any examples herein, in particular example 15, wherein the first resonator is a microstrip T-resonator or a microstrip L-resonator comprising: a transmission line; and an open-ended stub substantially perpendicular to the transmission line, wherein the open-ended stub is connected to the middle or the end of the transmission line, wherein an open end of the open-ended stub is configured to feed the second resonator.

Example 17 is a method according to any examples herein, in particular example 15, wherein the second resonator is a split-ring resonator comprising: one or more split rings, wherein each split ring of the one or more split rings includes one or more splits, wherein each split ring of the one or more split rings has one of: polygonal shape; circular shape; or any combination thereof.

Example 18 is a method according to any examples herein, in particular example 15, wherein a vector network analyzer or a rectifying block is configured to detect the metal within a detection range of the dual resonator device, wherein the vector network analyzer or the rectifying block is coupled to the first resonator, wherein the detection range of the dual resonator device is determined by the configuration of the first resonator and the second resonator, wherein the vector network analyzer is configured to measure the transmission scattering parameters, and wherein the rectifying block is configured to rectify AC input signals of the first resonator into DC output signals.

Example 19 is a method according to any examples herein, in particular example 15, wherein the output of the vector network analyzer or the rectifying block is processed and shown on a display, wherein the display comprises: liquid crystal display; light-emitting diode; organic light-emitting diode; or electronic paper.

Example 20 is an apparatus according to any examples herein, wherein the apparatus comprises: a sensor layer, wherein the sensor layer comprises one or more dual resonator sensors, an electronics layer, wherein the electronics layer comprises circuitry that controls the sensor layer, and a display layer, wherein the display layer comprises a display that illustrates the scanned surface and detected objects, wherein the display layer is controlled by the electronics layer.

Example 21 is an apparatus of a dual resonator sensor comprising: a planar dielectric substrate, a microstrip T-resonator on the first surface of the planar dielectric substrate and a split-ring resonator on the second surface of the planar dielectric substrate, wherein the stub of the microstrip T-resonator is chamfered or filleted.

Example 22 is an apparatus of a dual resonator sensor comprising: a planar dielectric substrate, a microstrip T-resonator on the first surface of the planar dielectric substrate, and a split-ring resonator on the second surface of the planar dielectric substrate, wherein the shape of each ring of one or more rings of the split-ring resonator comprise one of circular, polygonal, or any combination thereof.

Example 23 is an apparatus of a dual resonator sensor comprising: a planar dielectric substrate, a microstrip T-resonator on the first surface of the planar dielectric substrate, and a split-ring resonator on the second surface of the planar dielectric substrate, wherein the split-ring resonator comprises one or more splits.

Example 24 is an apparatus of a dual resonator sensor comprising: a planar dielectric substrate, a microstrip T-resonator on the first surface of the planar dielectric substrate, a split-ring resonator on the second surface of the planar dielectric substrate, and two or more reference ground conductors for the microstrip T-resonator, and the split-ring resonator, wherein the ground conductors substantially overlap.

We claim:

1. An apparatus of a dual resonator device, the apparatus comprising:
a planar dielectric substrate to provide electrical insulation;
a microstrip L-resonator on a first surface of the planar dielectric substrate, wherein the microstrip L-resonator includes:
a transmission line; and
an open-ended stub substantially perpendicular to the transmission line, wherein the open-ended stub is connected to one end of the transmission line;
an L-ground conductor on a second surface of the planar dielectric substrate, wherein the L-ground conductor substantially overlaps with the microstrip L-resonator;
a split-ring resonator on the second surface of the planar dielectric substrate, wherein the split-ring resonator includes:
one or more split rings, wherein each split ring of the one or more split rings includes one or more splits;
an S-ground conductor on the first surface of the planar dielectric substrate, wherein the S-ground conductor substantially overlaps with the split-ring resonator; and
a rectifying block to rectify AC signals from the microstrip L-resonator into DC output signals.

2. The apparatus of claim 1, wherein the microstrip L-resonator includes:
one or more open-ended stubs, wherein each open-ended stub of the one or more open-ended stubs is configured to feed the split-ring resonator.

3. The apparatus of claim 1, wherein the microstrip L-resonator and the split-ring resonator are to resonate at a same frequency.

4. The apparatus of claim 1, wherein each split ring of the one or more split rings of the split-ring resonator has one of:
polygonal shape;
circular shape; or
any combination thereof.

5. The apparatus of claim 1, wherein the planar dielectric substrate comprises one or more dielectric materials.

6. The apparatus of claim 1, wherein the open-ended stub of the microstrip L-resonator has one of:
a curved shape;
a tapered shape;
a rectangular shape;
a hexagonal shape; or
any combination thereof.

7. The apparatus of claim 1, wherein the microstrip L-resonator has a first resonant frequency, wherein the split-ring resonator has a second resonant frequency, wherein the first resonant frequency or the second resonant frequency is in microwave, millimeter wave, or terra hertz communication bands.

8. The apparatus of claim 1, wherein one or more surfaces of the L-ground conductor substantially overlap with one or more surfaces of the S-ground conductor.

9. An apparatus of a dual resonator sensor comprising:
a planar dielectric substrate to provide electrical insulation;
a first resonator on a first surface of the planar dielectric substrate;
a first ground conductor on a second surface of the planar dielectric substrate, wherein the first ground conductor substantially overlaps with the first resonator;
a second resonator on the second surface of the planar dielectric substrate, wherein the first resonator is to feed the second resonator; and
a second ground conductor on the first surface of the planar dielectric substrate, wherein the second ground conductor substantially overlaps with the second resonator.

10. The apparatus of claim 9, wherein the first resonator is a microstrip T-resonator or a microstrip L-resonator, wherein the microstrip T-resonator or the microstrip L-resonator includes:
a transmission line; and
an open-ended stub substantially perpendicular to the transmission line, wherein the open-ended stub is connected to a middle or an end of the transmission line, and wherein an open end of the open-ended stub is to feed the second resonator.

11. The apparatus of claim 9, wherein the second resonator is a split-ring resonator comprising:
one or more split rings, wherein each split ring of the one or more split rings includes one or more splits, and wherein each split ring of the one or more split rings has one of:
polygonal shape;
circular shape; or
any combination thereof.

12. The apparatus of claim 9, wherein the first resonator and the second resonator are configured to resonate at a same frequency.

13. The apparatus of claim 9, wherein the planar dielectric substrate constitutes one or more dielectric materials.

14. The apparatus of claim 9, wherein one or more surfaces of the first ground conductor substantially overlap with one or more surfaces of the second ground conductor.

15. A method of metal detection using a dual resonator device, the method comprising:
applying a wideband signal source to a first resonator, wherein the wideband signal source is configured to sweep a signal within a frequency range, wherein resonant frequency of the first resonator lies within the frequency range of the wideband signal source;
feeding a second resonator through the first resonator, wherein the second resonator is electrically isolated from the first resonator; and
detecting a metal by sensing a perturbation in scattering parameters or DC response from the first resonator.

16. The method of claim 15, wherein the first resonator is a microstrip T-resonator or a microstrip L-resonator comprising:
a transmission line; and
an open-ended stub substantially perpendicular to the transmission line, wherein the open-ended stub is connected to a middle or an end of the transmission line, and wherein an open end of the open-ended stub is to feed the second resonator.

17. The method of claim 15, wherein the second resonator is a split-ring resonator comprising:
one or more split rings, wherein each split ring of the one or more split rings includes one or more splits, and wherein each split ring of the one or more split rings has one of:
polygonal shape;
circular shape; or
any combination thereof.

18. The method of claim 15, wherein a vector network analyzer or a rectifying block is to detect the metal within a detection range of the dual resonator device, wherein the vector network analyzer or the rectifying block is coupled to the first resonator, wherein the detection range of the dual resonator device is determined by a configuration of the first resonator and the second resonator, wherein the vector network analyzer is to measure the scattering parameters, and wherein the rectifying block is to rectify AC input signals of the first resonator into DC output signals.

19. The method of claim 18, wherein an output of the vector network analyzer or the rectifying block is processed and shown on a display, wherein the display comprises:
a liquid crystal display;
a light-emitting diode;
an organic light-emitting diode; or
an electronic paper.
